(19) United States
(12) Patent Application Publication
(10) Pub. No.: US 2025/0324511 A1
(43) Pub. Date: Oct. 16, 2025

(54) POWER SUPPLY DEVICE AND A METHOD OF MANUFACTURING THEREOF

(71) Applicant: KABUSHIKI KAISHA TOYOTA JIDOSHOKKI, Aichi (JP)

(72) Inventor: Yoshifumi AKITA, Aichi (JP)

(73) Assignee: KABUSHIKI KAISHA TOYOTA JIDOSHOKKI, Aichi (JP)

(21) Appl. No.: 19/066,615

(22) Filed: Feb. 28, 2025

(30) Foreign Application Priority Data
Mar. 11, 2024 (JP) 2024-036830

(51) Int. Cl. H05K 1/11; H05K 1/14; H05K 3/40

(52) U.S. Cl. CPC H05K 1/115; H05K 1/144; H05K 3/4038; H05K 2201/09572; H05K 2203/1121

(57) ABSTRACT

A power supply device includes a first circuit board, a second circuit, and a plurality of circuit board coupling members. Each of the circuit board coupling members includes a body portion, a first protruding portion, and a second protruding portion. The body portion determines positions of the first circuit board and the second circuit board. The first protruding portion positions the body portion relative to the first circuit board. The second protruding portion positions the body portion relative to the second circuit board. A plurality of first positioning holes in which the first protruding portions are fitted is formed in the first circuit board. A plurality of second positioning holes in which the second protruding portions are fitted is formed in the second circuit board.

### CROSS-REFERENCE OF THE RELATED APPLICATION

This application claims priority to Japanese Patent Application No. 2024-036860 filed on Mar. 11, 2024, the entire disclosure of which is incorporated herein by reference.

### BACKGROUND ART

The present disclosure relates to a power supply device and a method of manufacturing the power supply device.

A circuit board, a method of manufacturing of the circuit board, and pillar-shaped terminals for the circuit board are disclosed in Japanese Patent Application Publication No. 2016-021550. This circuit board includes a first circuit board and a second circuit board connected to the first circuit board. A plurality of electrodes is disposed on a main surface of the first circuit board. A plurality of the pillar-shaped terminals to be used for connection between the first circuit board and the second circuit board is joined onto the corresponding electrodes through solder portions. The pillar-shaped terminals are each formed of a pillar-shaped terminal body and a solder blocking layer. The pillar-shaped terminal body is made of an electrically conductive material. The solder blocking layer is made of a material having solder wettability lower than solder wettability of the pillar-shaped terminal body and wraps a central region of an outer peripheral surface of the pillar-shaped terminal body in a height direction thereof. The pillar-shaped terminal body has a shape that is vertically symmetrical across the solder blocking layer. An area of a region of the outer peripheral surface of the pillar-shaped terminal body, which is not wrapped by the solder blocking layer, is larger than that of a region of the outer peripheral surface, which is wrapped by the solder blocking layer.

In the above-described prior art, the first circuit board and the second circuit board are coupled to each other through the plurality of the pillar-shaped terminals. However, no consideration is given at all to positioning of the first circuit board and the second circuit board for their coupling.

The present disclosure is directed to providing a power supply device in which two circuit boards are easily positioned for their coupling and a manufacturing method of the power supply device.

### SUMMARY

In accordance with an aspect of the present disclosure, there is provided a power supply device that includes a first circuit board, a second circuit board that is disposed so that the second circuit board faces the first circuit board, and a plurality of circuit board coupling members through which the first circuit board is coupled to the second circuit board. Each of the circuit board coupling members includes a body portion, a first protruding portion, and a second protruding portion. The body portion determines positions of the first circuit board and the second circuit board in a direction in which the first circuit board and the second circuit board face each other with one end surface of the body portion in contact with the first circuit board and with the other end surface of the body portion in contact with the second circuit board. The first protruding portion protrudes from the one end surface of the body portion and positions the body portion relative to the first circuit board in a direction perpendicular to the direction in which the first circuit board and the second circuit board face each other. The second protruding portion protrudes from the other end surface of the body portion and positions the body portion relative to the second circuit board in the direction perpendicular to the direction in which the first circuit board and the second circuit board face each other. A plurality of first positioning holes in which the first protruding portions are fitted is formed in the first circuit board. A plurality of second positioning holes in which the second protruding portions are fitted is formed in the second circuit board.

In accordance with another aspect of the present disclosure, there is provided a method of manufacturing the aforementioned power supply device that further includes a conductive member through which the first circuit board and the second circuit board are electrically connected to each other, wherein the first circuit board has a first through hole through which the conductive member passes, the second circuit board has a second through hole through which the conductive member passes, and the conductive member is fixed to the first circuit board and the second circuit board by solder, the method including a first step of coupling the first circuit board and the second circuit board through the plurality of circuit board coupling members, and a second step of, after the first step, inserting the conductive member into the first through hole and the second through hole.

Other aspects and advantages of the disclosure will become apparent from the following description, taken in conjunction with the accompanying drawings, illustrating by way of example the principles of the disclosure.

### BRIEF DESCRIPTION OF THE DRAWINGS

The disclosure, together with objects and advantages thereof, may best be understood by reference to the following description of the embodiments together with the accompanying drawings in which:

FIG. 1 is a perspective view illustrating a power supply device according to an embodiment of the present disclosure;

FIG. 2 is a cross-sectional view taken along a line II-II illustrated in FIG. 1;

FIG. 3 is a plan view schematically illustrating a lower circuit board;

FIG. 4 is a plan view schematically illustrating an upper circuit board;

FIG. 5 is a partially enlarged view of the power supply device according to the embodiment of the present disclosure;

FIG. 6 is a perspective view illustrating a circuit board coupling member;

FIG. 7 is a perspective view illustrating a conductive member;

FIG. 8 is a partially enlarged view of the power supply device according to the embodiment of the present disclosure;

FIG. 9 is a cross-sectional view illustrating a method of manufacturing the power supply device according to the embodiment of the present disclosure;

FIG. 10 is a cross-sectional view illustrating the method of manufacturing the power supply device according to the embodiment of the present disclosure;

FIG. 11 is a cross-sectional view illustrating the method of manufacturing the power supply device according to the embodiment of the present disclosure;

FIG. 12 is a cross-sectional view illustrating the method of manufacturing the power supply device according to the embodiment of the present disclosure;

FIG. 13 is a cross-sectional view illustrating the method of manufacturing the power supply device according to the embodiment of the present disclosure;

FIG. 14 is an exploded perspective view illustrating an example of a common power supply device according to a comparative example; and

FIGS. 15A and 15B are perspective views illustrating an example of a common connecting component according to another comparative example.

### DETAILED DESCRIPTION OF THE PREFERRED EMBODIMENTS

The following will describe an embodiment of the present disclosure with reference to the drawings. Note that identical or substantially identical components have the same reference numerals and may not be reiterated.

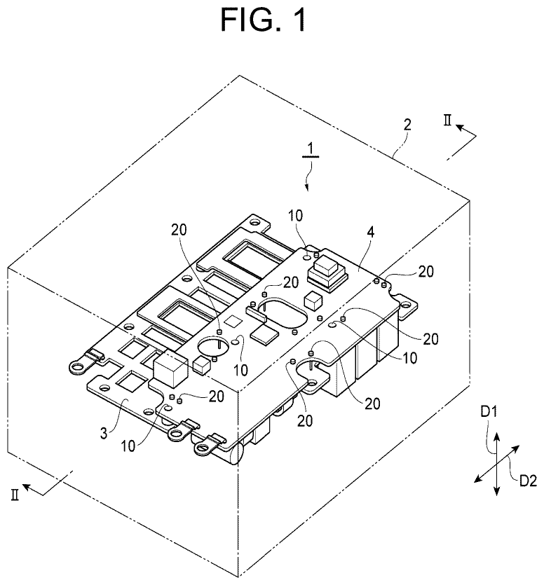

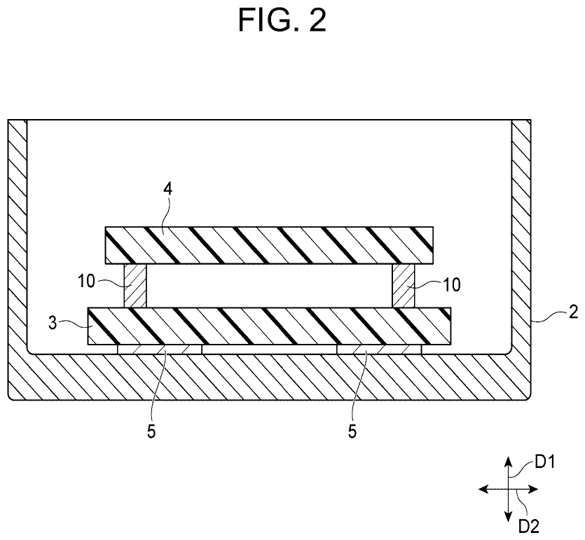

FIG. 1 is a perspective view illustrating a power supply device 1 according to an embodiment of the present disclosure. FIG. 2 is a cross-sectional view taken along a line II-II illustrated in FIG. 1. The power supply device 1 is entirely covered by a housing 2. The housing 2 is formed in a box shape, for example; however, the shape of the housing 2 is not limited thereto.

The power supply device 1 is, for example, a part of a DC-DC converter. The power supply device 1 includes a lower circuit board 3 (first circuit board), an upper circuit board 4 (second circuit board), circuit board coupling members 10, and conductive members 20. The lower circuit board 3 and the upper circuit board 4 are accommodated in the housing 2. The lower circuit board 3 is thermally coupled to the housing 2. A direction D1 illustrated in FIG. 1 and subsequent figures is a direction in which the lower circuit board 3 and the upper circuit board 4 face each other. A direction D2 is a direction perpendicular to the direction D1.

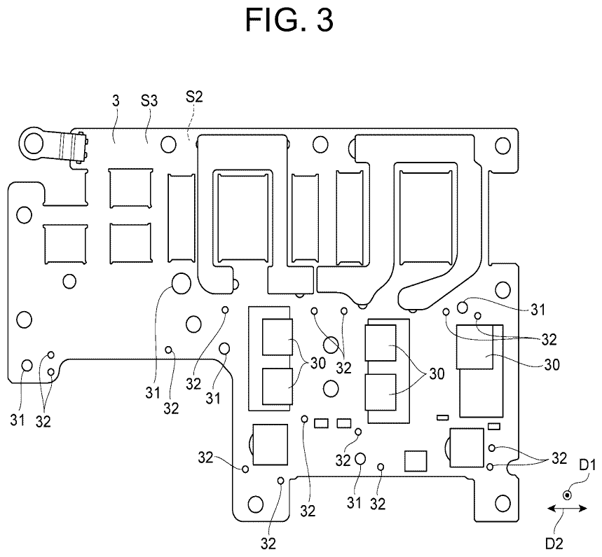

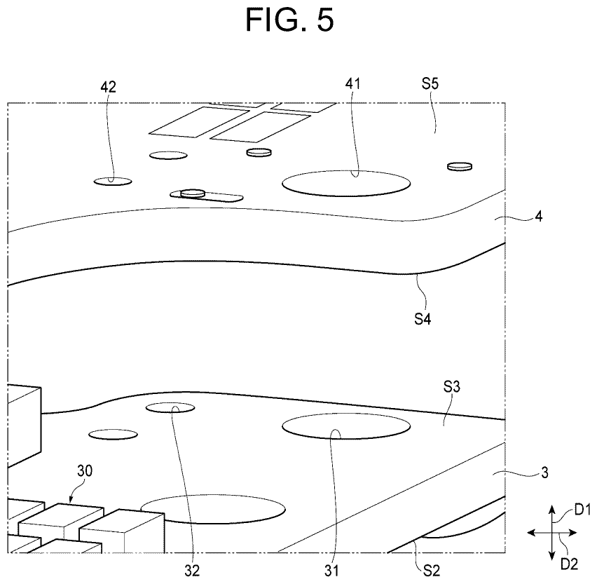

FIG. 3 is a plan view schematically illustrating the lower circuit board 3. FIG. 5 is a partially enlarged view of the power supply device 1 according to the embodiment of the present disclosure. In FIG. 5, the circuit board coupling members 10 and the conductive members 20 are omitted for convenience. The lower circuit board 3 has a main surface S3 and a main surface S2. The main surface S3 of the lower circuit board 3 is a surface perpendicular to the direction D1. The main surface S3 is an upper main surface (a surface near the upper circuit board 4) of the lower circuit board 3.

A wiring pattern, which is not illustrated, is formed on the lower circuit board 3. Electronic components 30 such as power elements are mounted on the wiring pattern. The power elements are electronic components from which a large amount of heat is generated. The electronic components 30 from which a large amount of heat is generated, such as a transformer and a reactor, may be mounted on the lower circuit board 3.

As an example of the power elements corresponding to the electronic components 30, a main MOSFET, a reset MOSFET, a synchronous rectification MOSFET, and a snubber MOSFET are mounted on the main surface S3 of the lower circuit board 3.

For example, a pattern winding of a transformer on a primary side thereof is formed on the main surface S2 opposite to the main surface S3 of the lower circuit board 3, and a wiring made of a copper plate is soldered to the wiring pattern on a corresponding region of the main surface S3. Thus, the pattern winding on the main surface S2 and the wiring on the main surface S3 form the transformer together with a core, which is not illustrated. The main surface S2 is a lower main surface of the lower circuit board 3.

The lower circuit board 3 has positioning holes 31 (first positioning hole) and through holes 32 (first through hole). The positioning holes 31 and the through holes 32 are holes formed in the lower circuit board 3 and extend through the lower circuit board 3. The lower circuit board 3 has a plurality of the positioning holes 31 and a plurality of the through holes 32. The positioning holes 31 and the through holes 32 are each formed in a circular shape. A diameter of each of the positioning holes 31 is greater than that of each of the through holes 32. The positioning holes 31 are holes into which the circuit board coupling members 10, which will be described later, are fitted. The through holes 32 are holes through which the conductive members 20, which will be described later, pass. When viewed in the direction D1, the wiring pattern, which is not illustrated, is formed around the positioning holes 31 and the through holes 32 on the lower circuit board 3.

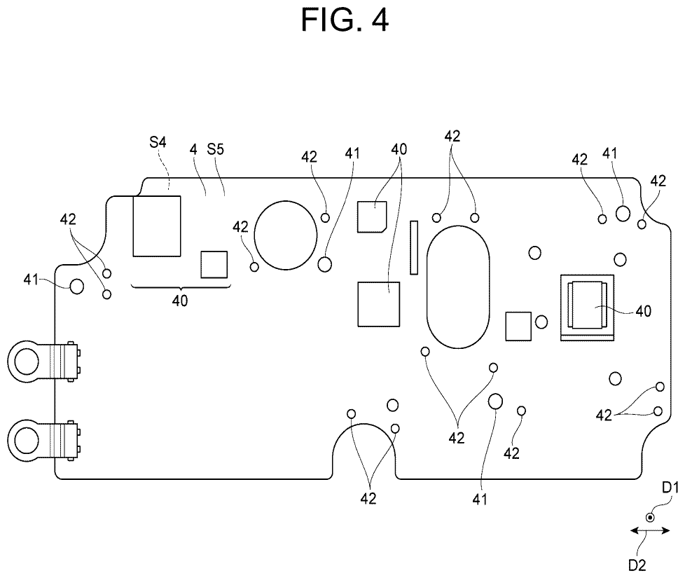

FIG. 4 is a plan view schematically illustrating the upper circuit board 4. The upper circuit board 4 is disposed so that the upper circuit board 4 faces the lower circuit board 3 in the direction D1. The upper circuit board 4 is located opposite to a bottom portion of the housing 2 across the lower circuit board 3. Accordingly, the lower circuit board 3 is located closer to the bottom portion of the housing 2 than the upper circuit board 4 (see FIG. 2). The upper circuit board 4 and the lower circuit board 3 are arranged in parallel with each other along the direction D1. The upper circuit board 4 has a main surface S4 and a main surface S5. The main surface S4 of the upper circuit board 4 is a surface perpendicular to the direction D1. The main surface S4 is a lower main surface of the upper circuit board 4. That is, the main surface S4 faces the main surface S3 of the lower circuit board 3 in the direction D1.

A wiring pattern, which is not illustrated, is formed on the upper circuit board 4. Electronic components 40 such as control elements are mounted on the wiring pattern. As illustrated in FIGS. 1 and 4, as an example of the control elements, an IC, a capacitor such as a film capacitor, and a resistor are mounted on the main surface S4 of the upper circuit board 4. As the electronic components other than the control elements, for example, a common coil and a fuse may be mounted. As an example, a signal connector is mounted on the main surface S5 opposite to the main surface S4 of the upper circuit board 4. The main surface S5 is an upper main surface of the upper circuit board 4.

The upper circuit board 4 has positioning holes 41 (second positioning hole) and through holes 42 (second through hole) (see FIG. 5). The positioning holes 41 and the through holes 42 are holes formed in the upper circuit board 4 and extend through the upper circuit board 4. The upper circuit board 4 has a plurality of the positioning holes 41 and a plurality of the through holes 42. The positioning holes 41 and the through holes 42 are each formed in a circular shape. A diameter of each of the positioning holes 41 is greater than that of each of the through holes 42. The positioning holes 41 are holes into which the circuit board coupling members 10, which will be described later, are fitted. The through holes 42 are holes through which the conductive members 20, which will be described later, pass. When viewed in the direction D1, the wiring pattern, which is not illustrated, is formed around the positioning holes 41 and the through holes 42 on the upper circuit board 4.

See FIG. 2 again. Heat dissipation members 5 are provided between the bottom portion of the housing 2 and the power supply device 1. The heat dissipation members 5 are members through which heat generated from the power supply device 1 is dissipated to the housing 2. The heat dissipation members 5 are each made of an insulating material, such as an insulating sheet; however, the material of the heat dissipation members 5 is not limited thereto. Each of the heat dissipation members 5 is preferably made of an insulating material with good thermal conductivity. A plurality of the heat dissipation members 5 is provided between the bottom portion of the housing 2 and the power supply device 1. The heat dissipation members 5 are arranged along the direction D2. Note that in FIG. 2, an illustration of the conductive members 20 is omitted for ease of the explanation.

As described above, members with good thermal conductivity, for example, copper members, are located in corresponding portions on which the power elements are disposed in the lower circuit board 3 and extends from the main surface S3 to the main surface S2. The heat generated from the power elements is dissipated to the housing 2 through the copper members and the heat dissipation members 5. The lower circuit board 3 and the housing 2 are thermally coupled to each other through the heat dissipation members 5, and the heat generated from the electronic components 30 mounted on the lower circuit board 3 is dissipated to the housing 2 through the copper members and the heat dissipation members 5.

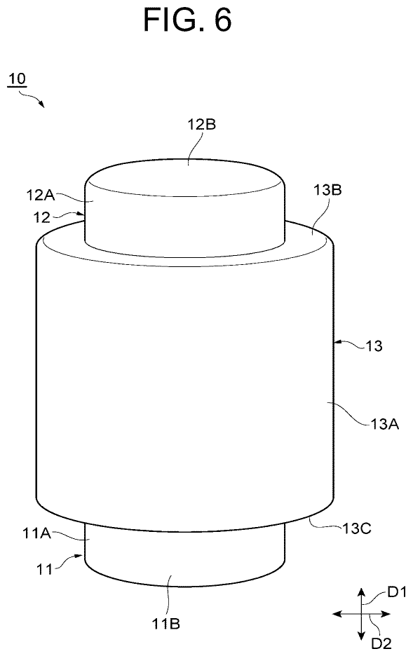

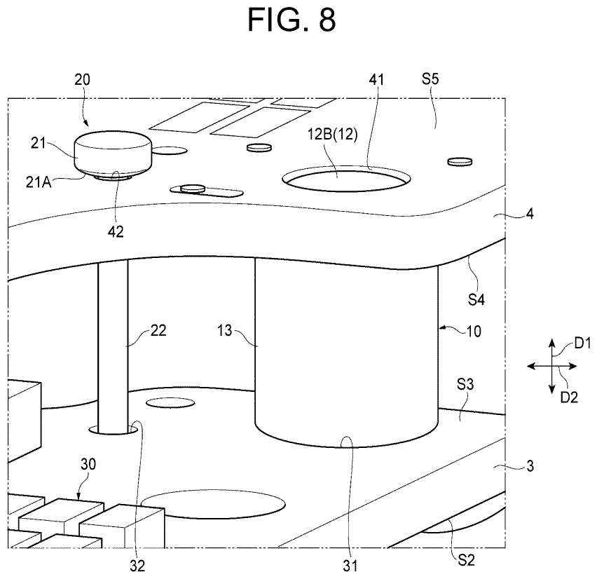

FIG. 6 is a perspective view illustrating one of the circuit board coupling members 10. FIG. 8 is a partially enlarged view of the power supply device 1 according to the embodiment of the present disclosure. Each of the circuit board coupling members 10 is a pillar-shaped member through which the lower circuit board 3 and the upper circuit board 4 are connected. That is, the circuit board coupling members 10 are interposed between the lower circuit board 3 and the upper circuit board 4. The power supply device 1 includes a plurality of the circuit board coupling members 10. Each of the circuit board coupling members 10 may have a solid structure or a hollow structure.

The circuit board coupling members 10 each have a body portion 13, a protruding portion 11 (first protruding portion), and a protruding portion 12 (second protruding portion). The body portion 13 has a columnar shape extending in the direction D1. The body portion 13 determines positions of the lower circuit board 3 and the upper circuit board 4 in the direction D1. That is, a length of the body portion 13 in the direction D1 is a distance between the lower circuit board 3 and the upper circuit board 4. In other words, the position of the upper circuit board 4 relative to the lower circuit board 3 is determined by the length of the body portion 13 in the direction D1, so that the lower circuit board 3 and the upper circuit board 4 are positioned in the direction D1.

The body portion 13 has a side surface 13A, a bottom surface 13C (one end surface), and a top surface 13B (the other end surface). The side surface 13A is, on opposite sides thereof in the direction D1, connected to the top surface 13B and the bottom surface 13C. The side surface 13A is an even curved surface. The top surface 13B and the bottom surface 13C are circular even surfaces perpendicular to the direction D1.

The protruding portion 11 of each of the circuit board coupling members 10 is a protrusion that is fitted in each of the positioning holes 31 of the lower circuit board 3. That is, each of the plurality of the positioning holes 31 in which the corresponding protruding portion 11 is fitted is formed in the lower circuit board 3. The protruding portion 11 positions the body portion 13 of each of the circuit board coupling members 10 relative to the lower circuit board 3 in the direction D2 perpendicular to the direction D1. When the protruding portion 11 is fitted in the corresponding positioning hole 31, the body portion 13 is positioned relative to the lower circuit board 3 in the direction D2. That is, ease of positioning indicates ease of fitting of the protruding portion 11 in the corresponding positioning hole 31. In the direction D2, the position of the protruding portion 11 is determined by determining the position of the corresponding positioning hole 31.

The protruding portion 11 is formed on the bottom surface 13C of the body portion 13. Specifically, the protruding portion 11 protrudes from the bottom surface 13C of the body portion 13. The protruding portion 11 is formed integrally with the body portion 13 by forging, for example. The protruding portion 11 may be fixed on the bottom surface 13C of the body portion 13 or may be provided inside the body portion 13 and extend out over the bottom surface 13C of the body portion 13 in the direction D1.

The protruding portion 11 has a substantially columnar shape extending in the direction D2. A length of the protruding portion 11 in the direction D1 is less than that of the body portion 13 in the direction D1. The body portion 13 is positioned relative to the lower circuit board 3 in the direction D2 by the protruding portion 11. As described above, in the direction D2, the position of the protruding portion 11 is determined by determining each of the positioning holes 31, that is, the position of the body portion 13 is determined by determining each of the positioning holes 31, so that the position of each of the circuit board coupling members 10 is determined.

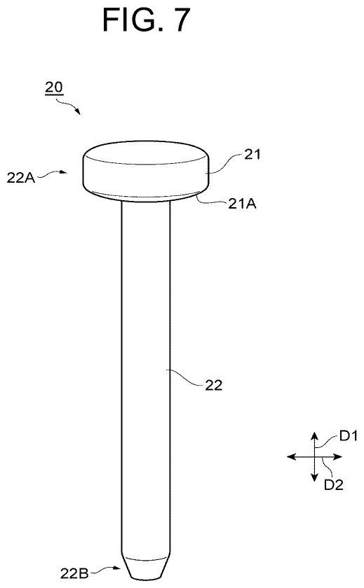

The protruding portion 11 has a side surface 11A and a bottom surface 11B. The side surface 11A is, at one end thereof in the direction D1, connected to the bottom surface 11B. The side surface 11 A is an even curved surface. The protruding portion 11 is fitted in the corresponding positioning hole 31 with the side surface 11A facing the corresponding positioning hole 31 (see FIG. 7). The bottom surface 11B is an even surface perpendicular to the direction D1. When viewed in the direction D1, the bottom surface 11B is formed in a circular shape that matches the shape of the positioning hole 31. Furthermore, when viewed in the direction D1, a center of the protruding portion 11 (bottom surface 11B) is aligned with a center of the body portion 13 (bottom surface 13C).

The protruding portion 12 is a protrusion of each of the circuit board coupling members 10, which is fitted in each of the positioning holes 41 of the upper circuit board 4. That is, each of the plurality of the positioning holes 41 in which the corresponding protruding portion 12 is fitted is formed in the upper circuit board 4. The protruding portion 12 positions the body portion 13 of each of the circuit board coupling members 10 relative to the upper circuit board 4 in the direction D2 perpendicular to the direction D1. Similarly to the protruding portion 11, when the protruding portion 12 is fitted in the corresponding positioning hole 41, the body portion 13 is positioned relative to the upper circuit board 4 in the direction D2. That is, ease of positioning indicates ease of fitting of the protruding portion 12 to the corresponding positioning hole 41. When the position of the positioning hole 41 is determined in the direction D2, the position of the protruding portion 12 is determined.

In fitting of each of the circuit board coupling members 10 to the lower circuit board 3 and the upper circuit board 4, the bottom surface 13C is in contact with the main surface S3 of the lower circuit board 3 and the top surface 13B is in contact with the main surface S4 of the upper circuit board 4. As a result, the body portion 13 of each of the circuit board coupling members 10 is positioned relative to the lower circuit board 3 and the upper circuit board 4. Accordingly, the upper circuit board 4 is positioned relative to the lower circuit board 3 by the circuit board coupling members 10. In other words, the body portion 13 determines the positions of the lower circuit board 3 and the upper circuit board 4 in the direction D1 in which the lower circuit board 3 and the upper circuit board 4 face each other with the bottom surface 13C in contact with the lower circuit board 3 and with the top surface 13B in contact with the upper circuit board 4.

The protruding portion 12 is provided on the top surface 13B of the body portion 13. Specifically, the protruding portion 12 protrudes from the top surface 13B of the body portion 13. The protruding portion 12 is formed integrally with the body portion 13 by forging, for example. The protruding portion 12 may be fixed on the top surface 13B of the body portion 13, and may be provided inside the body portion 13 and extend out over the top surface 13B of the body portion 13 in the direction D1.

The protruding portion 12 has a substantially columnar shape extending in the direction D2. A length of the protruding portion 12 in the direction D1 is less than that of the body portion 13 in the direction D1. The body portion 13 is positioned relative to the upper circuit board 4 in the direction D2 by the protruding portion 12. As described above, in the direction D2, the position of the protruding portion 12 is determined by determining the position of the corresponding positioning hole 41. That is, the position of the body portion 13, and indeed, the position of the circuit board coupling member 10 is determined by determining the position of the positioning hole 41.

The protruding portion 12 has a side surface 12A and a top surface 12B. The side surface 12A is, at one end thereof in the direction D1, connected to the top surface 12B. The side surface 12A is an even curved surface. The protruding portion 12 is fitted in the corresponding positioning hole 41 with the side surface 12A facing the corresponding positioning hole 41. The top surface 12B is an even surface perpendicular to the direction D1. When viewed in the direction D1, the top surface 12B is formed in a circular shape that matches the shape of the positioning hole 41. Furthermore, when viewed in the direction D1, a center of the protruding portion 12 (top surface 12B) is aligned with the center of the body portion 13 (top surface 13B).

The circuit board coupling members 10 each have electrical conductivity. The circuit board coupling members 10 are each made of metal such as copper (Cu). The protruding portion 11 of each of the circuit board coupling members 10 is fitted in the corresponding positioning hole 31, and the bottom surface 13C is fixed to the wiring pattern of the lower circuit board 3 by solder, which is not illustrated. The protruding portion 12 of each of the circuit board coupling members 10 is fitted in the corresponding positioning hole 41, and the top surface 13B is fixed to the wiring pattern of the upper circuit board 4 by solder, which is not illustrated. The lower circuit board 3 and the upper circuit board 4 are electrically connected to each other through the circuit board coupling members 10. That is, a current can flow through the circuit board coupling members 10. Specifically, the wiring pattern formed on the lower circuit board 3 and the wiring pattern formed on the upper circuit board 4 are electrically connected to each other through the circuit board coupling members 10. The circuit board coupling members 10 are current carrying connecting components through which a large current from the electronic components 30 flows. As a cross-sectional area of the body portion 13 of each of the circuit board coupling members 10 in the direction D2 increases, a current path when the circuit board coupling member 10 is electrically connected to the wiring pattern through the solder becomes wider, which reduces a resistance of the circuit board coupling member 10.

Solder 50, which will be described later, is provided between the bottom surface 13C and the main surface S3 of the lower circuit board 3. The bottom surface 13C is in contact with the solder 50 applied on the main surface S4. The solder 50, which will be described later, is provided between the top surface 13B and the main surface S4 of the upper circuit board 4. The top surface 13B is in contact with the solder 50 applied on the main surface S4.

As described above, the lower circuit board 3 and the upper circuit board 4 are coupled through the plurality of the circuit board coupling members 10. Here, the plurality of the circuit board coupling members 10 is arranged at positions such that the lower circuit board 3 and the upper circuit board 4 are stably coupled.

FIG. 7 is a perspective view illustrating one of the conductive members 20. The conductive members 20 are members through which the lower circuit board 3 and the upper circuit board 4 are electrically connected. That is, the conductive members 20 are interposed between the lower circuit board 3 and the upper circuit board 4. Specifically, one end portion 22A of each of the conductive members 20 passes through the corresponding through hole 42, and the other end portion 22B of the conductive member 20 passes through the corresponding through hole 32 (see FIG. 8). That is, the lower circuit board 3 has the through holes 32 through which the conductive members 20 pass, and the upper circuit board 4 has the through holes 42 through which the conductive members 20 pass.

The conductive members 20 are fixed to the lower circuit board 3 and the upper circuit board 4 by solder. The conductive members 20 are each made of metal such as copper (Cu), and each have electrical conductivity. Electrical signals are transmitted through the conductive members 20.

The power supply device 1 includes a plurality of the conductive members 20. The number of the conductive members 20 in the power supply device 1 is greater than the number of the circuit board coupling members 10. The positions of the conductive members 20 and the number of the conductive members 20 are determined as appropriate by determining positions of the through holes 32 and the through holes 42 in the lower circuit board 3 and the upper circuit board 4 as desired, respectively.

The conductive members 20 each have a core portion 22 and a retaining portion 21. The retaining portion 21 is formed at the one end portion 22A of the core portion 22 so that the retaining portion 21 protrudes from the core portion 22 perpendicularly to a direction in which the core portion 22 extends. The retaining portion 21 is caught on the lower circuit board 3 or the upper circuit board 4.

The retaining portion 21 is formed in the one end portion 22A of each of the conductive members 20. The retaining portion 21 has a substantially columnar shape extending in the direction D2. When viewed in the direction D1, a diameter of the retaining portion 21 is greater than that of each of the through holes 42 of the upper circuit board 4.

In the present embodiment, in a state where each of the conductive members 20 passes through the lower circuit board 3 and the upper circuit board 4, the retaining portion 21 is disposed on the main surface S5 of the upper circuit board 4. The retaining portion 21 has a bottom surface 21A. The bottom surface 21A of the retaining portion 21 is an even surface perpendicular to the direction D1 and faces the main surface S5 of the upper circuit board 4. In the present embodiment, the bottom surface 21A is in contact with the main surface S5. When the bottom surface 21A comes into contact with the main surface S5 of the upper circuit board 4, the retaining portion 21 is caught on the upper circuit board 4 (see FIG. 8). The retaining portion 21 is fixed to the upper circuit board 4 by solder.

The core portion 22 has a columnar shape extending in the direction D1. The other end portion 22B of the core portion 22 (conductive member 20) tapers toward a distal end of the core portion 22 in the direction D1. When viewed in the direction D1, a diameter of the core portion 22 is less than a diameter of the retaining portion 21. When viewed in the direction D1, the diameter of the core portion 22 is less than the diameter of each of the through holes 32 and the diameter of each of the through holes 42.

As described above, the body portion 13 of each of the circuit board coupling members 10 and the core portion 22 of each of the conductive members 20 have the columnar shape. The diameter of the core portion 22 in the direction D2 is less than a diameter of the body portion 13 in the direction D2. Thus, each of the conductive members 20 is narrower than the body portion 13 of each of the circuit board coupling members 10. In addition, the diameter of the core portion 22 along the direction D2 is less than the diameter of each of the through holes 32 and the diameter of each of the through holes 42 along the direction D2.

The other end portion 22B of the core portion 22 (conductive member 20) is fixed to the lower circuit board 3 by solder. The retaining portion 21 is formed integrally with the core portion 22 in the direction D1 by forging, for example. Specifically, the core portion 22 of each of the conductive members 20, at a side of the one end portion 22A, is integrated with the bottom surface 21A of the retaining portion 21. Accordingly, as illustrated in FIG. 7, the conductive member 20 has a nail-like shape.

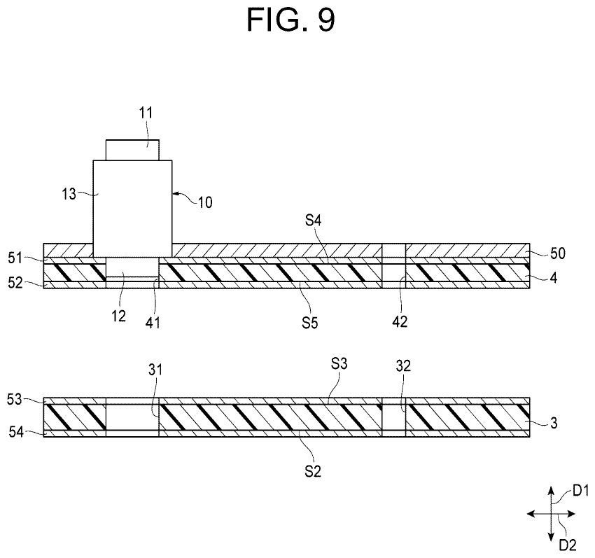

The following will describe a method of manufacturing the power supply device 1. FIG. 9 to FIG. 13 are cross-section views illustrating a method of manufacturing the power supply device 1 according to the embodiment of the present disclosure. A process of soldering in the manufacturing method described below is generally called reflow soldering. In the reflow soldering, for example, infrared rays or hot air is used for melting solder in a reflow oven. Alternatively, the power supply device 1 may be manufactured by laser soldering using laser light as a heat source. Laser soldering provides more enhanced precision.

First, as illustrated in FIG. 9, the solder 50 is applied on the main surface S4 of the upper circuit board 4. The solder 50 is applied on portions of the main surface S4 where it is necessary to fix components and ensure electrical conductivity, such as portions where a wiring pattern 51 is formed and the electronic components 40 and the circuit board coupling members 10 are disposed. The solder 50 that is applied on the main surface S4 may be a solder paste.

Subsequently, the protruding portion 12 of each of the circuit board coupling members 10 is fitted into the corresponding positioning hole 41 from a side of the main surface S4 of the upper circuit board 4. At this time, the solder 50 is interposed between the top surface 13B of each of the circuit board coupling members 10 and the wiring pattern 51 of the upper circuit board 4. Accordingly, the circuit board coupling members 10 are disposed on the main surface S4 of the upper circuit board 4. The electronic components 40 are disposed on the main surface S4 on which the solder 50 has been applied. Then, the upper circuit board 4 passes through the reflow oven in order to melt the solder 50 applied on the upper circuit board 4, and then, is cooled. Note that the word “cooling” used herein is not limited to actively cooling, but also includes cooling in which a temperature of the upper circuit board 4 approaches a room temperature by leaving the upper circuit board 4 as is after passing through the reflow oven. With this step, the circuit board coupling members 10 and the electronic components 40 are fixed to the upper circuit board 4 by the solder 50, so that the circuit board coupling members 10 and the electronic components 40 are mounted on the upper circuit board 4. Here, the circuit board coupling members 10 and the electronic components 40 are simultaneously fixed to the upper circuit board 4 by the solder 50, which enhances efficiency of a work of mounting the electronic components 40 on the main surface S4.

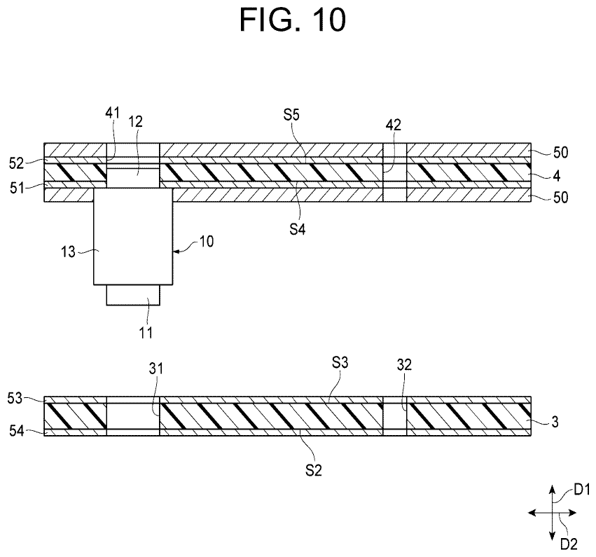

Then, as illustrated in FIG. 10, the upper circuit board 4 is turned over in a thickness direction (direction D1) of the upper circuit board 4. Next, the solder 50 is applied on the main surface S5 opposite to the main surface S4. The solder 50 is applied on portions of the main surface S5 where it is necessary to fix components and ensure electrical conductivity, such as portions where a wiring pattern 52 is formed and the electronic components 40 are disposed. Note that the solder 50 may be applied on the main surface S5 before the upper circuit board 4 is turned over. After that, the electronic components 40 are attached on the main surface S5 on which the solder 50 has been applied. The upper circuit board 4 passes through the reflow oven to melt the solder 50, and then, is cooled. Thus, the electronic components 40 are fixed to and mounted on the main surface S5.

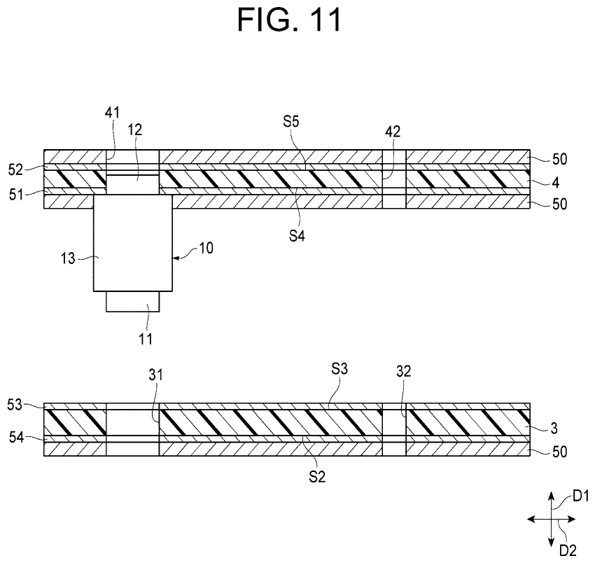

Subsequently, as illustrated in FIG. 11, the solder 50 is applied on the main surface S2 opposite to the main surface S3 of the lower circuit board 3. The solder 50 is applied on portions of the main surface S2 where it is necessary to fix components and ensure electrical conductivity, such as portions where a wiring pattern 54 is formed and the electronic components 30 are disposed. Note that the solder 50 may be applied on the main surface S2 when the main surface S2 of the lower circuit board 3 faces the upper circuit board 4. After that, the electronic components 30 are attached on the main surface S2 on which the solder 50 has been applied. The lower circuit board 3 passes through the reflow oven to melt the solder 50, and then, is cooled. Thus, the electronic components 30 are fixed to and mounted on the main surface S2.

Next, the solder 50 is applied on the main surface S3 of the lower circuit board 3. The solder 50 is applied on portions of the main surface S3 where it is necessary to fix components and ensure electrical conductivity, such as portions where a wiring pattern 53 is formed and the electronic components 30 and the circuit board coupling members 10 are disposed. In a case where the electronic components 30 are mounted on the main surface S3 after that, the electronic components 30 may be attached on the main surface S3 on which the solder 50 has been applied.

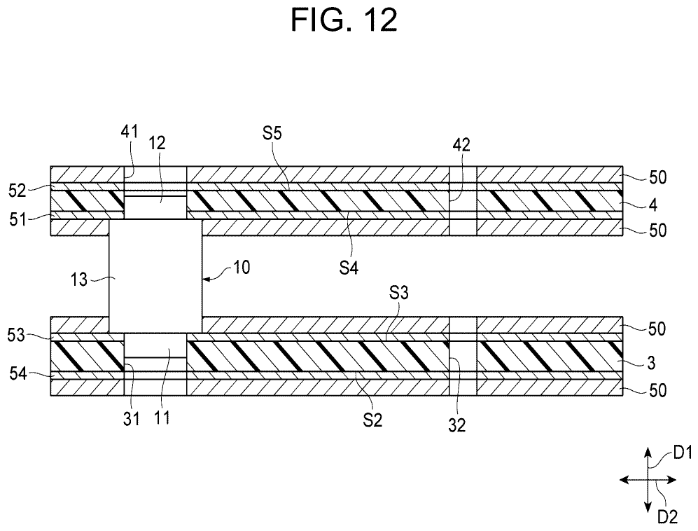

Subsequently, as illustrated in FIG. 12, the protruding portion 11 of each of the circuit board coupling members 10 already fixed to the upper circuit board 4 by the solder 50 is fitted into the corresponding positioning hole 31 from a side of the main surface S3 of the lower circuit board 3, so that the lower circuit board 3 and the upper circuit board 4 are coupled to each other through the circuit board coupling member 10 (first step). Here, the solder 50 is interposed between the bottom surface 13C of each of the circuit board coupling members 10 and the wiring pattern 53 of the lower circuit board 3.

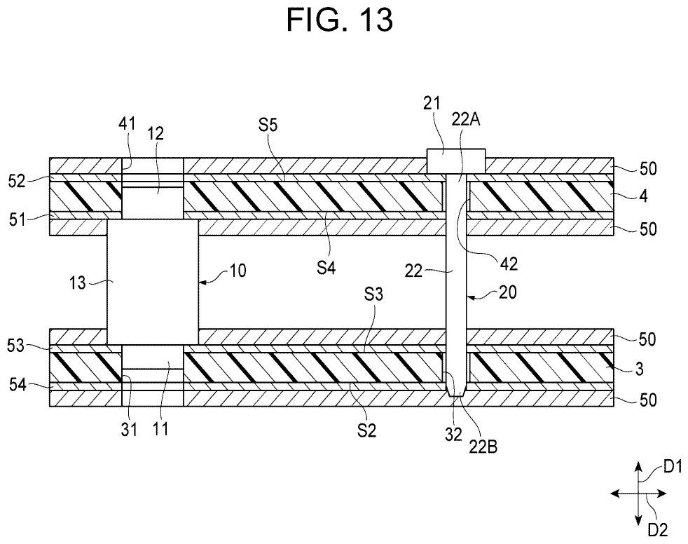

After these steps are performed, as illustrated in FIG. 13, the other end portion 22B of each of the conductive members 20 passes through the corresponding through hole 42 of the upper circuit board 4 and then through the corresponding through hole 32 of the lower circuit board 3, and the one end portion 22A of the conductive member 20 passes through the corresponding through hole 42 of the upper circuit board 4. That is, each of the conductive members 20 is inserted through the corresponding through hole 42 and then into the corresponding through hole 32 (second step).

In this state, the upper circuit board 4 and the lower circuit board 3 pass through the reflow oven to melt the solder 50 applied on the upper circuit board 4 and the lower circuit board 3, and then, are cooled. With this step, the electronic components 30 are fixed to the main surface S2 and the main surface S3 by the solder 50, the circuit board coupling members 10 are fixed to the lower circuit board 3 by the solder 50, and the conductive members 20 are fixed to the lower circuit board 3 and the upper circuit board 4 by the solder 50. That is, after the lower circuit board 3 and the upper circuit board 4 pass through the reflow oven to melt the solder 50, and then, is cooled, so that the circuit board coupling members 10 are fixed to the lower circuit board 3 while the one end portion 22A of each of the conductive members 20 is fixed to the upper circuit board 4 and the other end portion 22B of the conductive member 20 is fixed to the lower circuit board 3. In other words, following the above-described second step, the circuit board coupling members 10 and the conductive members 20 are fixed to the lower circuit board 3 and the upper circuit board 4 by melting the solder 50 applied on the lower circuit board 3 and the upper circuit board 4 and cooling the melted solder 50 (third step).

In the method of manufacturing of the above-described power supply device 1, in a state where the lower circuit board 3 and the upper circuit board 4 are positioned in the direction D1 and the direction D2 by the circuit board coupling members 10, the conductive members 20 are inserted through the through holes 32 and the through holes 42. In order to position the lower circuit board 3 and the upper circuit board 4 in the direction D1 and the direction D2 in a state where the circuit board coupling members 10 are fitted (after the first step), it is preferable that two or more circuit board coupling members 10 are fitted into two or more positioning holes 31 and two or more positioning holes 41 or each of the circuit board coupling members 10 with a cross-sectional area having an polygonal shape along the direction D2 is fitted into the corresponding positioning hole 31 and the corresponding positioning hole 41.

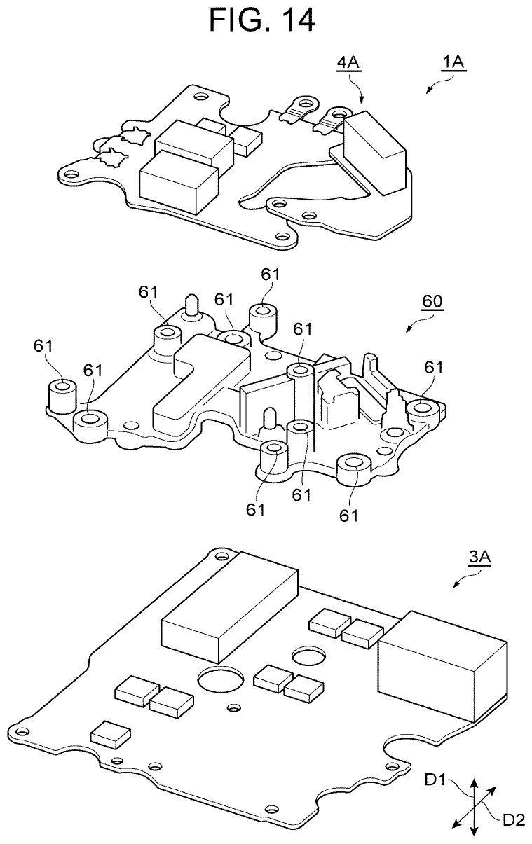

FIG. 14 is an exploded perspective view illustrating an example of a common power supply device 1A according to a comparative example. The power supply device 1A includes a lower circuit board 3A and an upper circuit board 4A instead of the lower circuit board 3 and the upper circuit board 4 in the power supply device 1. In addition, the power supply device 1A includes a base plate 60 that is disposed between the lower circuit board 3A and the upper circuit board 4A. The upper circuit board 4A has positioning holes, which are not illustrated, instead of the positioning holes 41. The base plate 60 is a component for guiding the lower circuit board 3A and the upper circuit board 4A so that they are coupled in correct positions. A plurality of bosses 61 is fixed to the base plate 60. In such a power supply device 1A, the lower circuit board 3A and the base plate 60 are fixed to each other. Then, the bosses 61 are fitted into the positioning holes of the upper circuit board 4A, and the base plate 60 and the upper circuit board 4A are fixed to each other by screws, which are not illustrated.

In a case where dimensional accuracy between positions of the bosses 61 and positions of the corresponding positioning holes, which are not illustrated, of the upper circuit board 4A exceeds an acceptable range when viewed in the direction D1, the bosses 61 and the positioning holes of the upper circuit board 4A are not aligned with each other, so that it is difficult to couple the bosses 61 and the positioning holes of the upper circuit board 4A to each other and fix the base plate 60 to the upper circuit board 4A with the bosses 61 interposed therebetween by the screws, which are not illustrated. Additionally, since the plurality of the bosses 61 and the plurality of the screws are required, manufacturing costs of the power supply device 1A increases. Furthermore, the lower circuit board 3A and the upper circuit board 4A are increased in size, which leads to an increase in size of the power supply device 1A.

For such a problem, in the power supply device 1 of the present embodiment, the plurality of the circuit board coupling members 10 is used for coupling the lower circuit board 3 and the upper circuit board 4 to each other. The positions of the lower circuit board 3 and the upper circuit board 4 in the direction D1 are determined by the body portion 13 of each of the plurality of the circuit board coupling members 10. Specifically, the body portion 13 determines the positions of the lower circuit board 3 and the upper circuit board 4 in the direction D1 in which the lower circuit board 3 and the upper circuit board 4 face each other with the bottom surface 13C of the body portion 13 in contact with the lower circuit board 3 and with the top surface 13B of the body portion 13 in contact with the upper circuit board 4. The protruding portion 11 protruding from the bottom surface 13C of the body portion 13 is fitted into the corresponding positioning hole 31 of the lower circuit board 3, and the protruding portion 12 protruding from the top surface 13B of the body portion 13 is fitted into the corresponding positioning hole 41 of the upper circuit board 4. As a result, the circuit board coupling members 10 are positioned in the direction D2 of the lower circuit board 3 and the upper circuit board 4 relative to the lower circuit board 3 and the upper circuit board 4. When such a plurality of the circuit board coupling members 10 is provided, the bosses 61 and the screws, which are not illustrated, as in the comparative example need not be used for coupling the lower circuit board 3 and the upper circuit board 4 to each other. This configuration reduces the manufacturing costs of the power supply device 1. In addition, in this configuration, the lower circuit board 3 and the upper circuit board 4 are decreased in size, which leads to a decrease of the power supply device 1 in size. Furthermore, since the circuit board coupling members 10 are not fixed to the other component, unlike the bosses 61, the circuit board coupling members 10 are movable independently in the direction D2. Accordingly, the circuit board coupling members 10 have a high degree of freedom in arrangement between the lower circuit board 3 and the upper circuit board 4. In addition, the position of the lower circuit board 3 relative to the upper circuit board 4 is adjustable in the direction D1 by the length of the body portion 13 of each of the circuit board coupling members 10. This makes it easier to position the lower circuit board 3 and the upper circuit board 4 for their coupling, which enhances the efficiency of the work. Accordingly, in the present embodiment, consideration is given to positioning of the lower circuit board 3 and the upper circuit board 4 for their coupling.

Furthermore, the lower circuit board 3 and the upper circuit board 4 are connected to each other at desired positions of the lower circuit board 3 and the upper circuit board 4, so that a design of the wiring patterns formed on the lower circuit board 3 and the upper circuit board 4 may be optimized. This decreases the lower circuit board 3 and the upper circuit board 4 in size.

In the present embodiment, the circuit board coupling members 10 each have electrical conductivity. Accordingly, since the circuit board coupling members 10 also serve as the current carrying connecting components, there is no need to separately provide current carrying connecting components for a large current other than the circuit board coupling members 10 on the lower circuit board 3 and the upper circuit board 4. As a result, layouts of the lower circuit board 3 and the upper circuit board 4 are simplified. Thus, the protruding portion 11 of each of the circuit board coupling members 10 is easily fitted into the corresponding positioning hole 31 of the lower circuit board 3, and the protruding portion 12 of the circuit board coupling member 10 is easily fitted into the corresponding positioning hole 41 of the upper circuit board 4, which makes it easier to position the lower circuit board 3 and the upper circuit board 4 for their coupling.

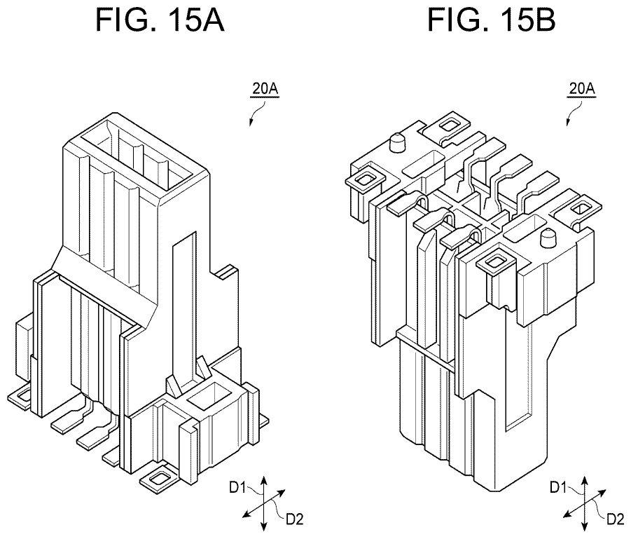

FIGS. 15A and 15B are perspective views illustrating an example of a common connecting component 20A according to another comparative example. The connecting component 20A illustrated in FIG. 15A and the connecting component 20A illustrated in FIG. 15B are oriented toward opposite sides in the direction D1. As illustrated in FIGS. 15A and 15B, the connecting component 20A for electrical signal lines, which is called a board-to-board (B to B) connector, is conventionally used for connection between electrical signal lines on the lower circuit board 3 and the electrical signal lines on the upper circuit board 4. In this case, the electrical signal lines on the lower circuit board 3 and the upper circuit board 4 need to be gathered to the connecting component 20A.

However, in the present embodiment, the conductive members 20 through which the lower circuit board 3 and the upper circuit board 4 are electrically connected are provided instead of the connecting component 20A. In such a configuration, the conductive members 20 pass through the through holes 32 of the lower circuit board 3 and the through holes 42 of the upper circuit board 4. When the electrical signal lines on the lower circuit board 3 and the electrical signal lines on the upper circuit board 4 are connected to each other through the plurality of the conductive members 20, the electrical signal lines on the lower circuit board 3 and the upper circuit board 4 need not be gathered to a point. Accordingly, regions of the lower circuit board 3 and the upper circuit board 4, which are occupied for the connection between the electrical signal lines on the lower circuit board 3 and the electrical signal lines on the upper circuit board 4, are reduced, so that the layouts of the lower circuit board 3 and the upper circuit board 4 are simplified. Thus, the protruding portion 11 of each of the circuit board coupling members 10 is easily fitted into the corresponding through hole 32 of the lower circuit board 3 and the protruding portion 12 of each of the circuit board coupling members 10 is easily fitted into the corresponding through hole 42 of the upper circuit board 4, which makes it easier to position the lower circuit board 3 and the upper circuit board 4 for their coupling. Furthermore, since each of the conductive members 20 is smaller than the connecting component 20A, a space occupied by a mechanism for the connection between the electrical signal lines of the lower circuit board 3 and the electrical signal lines of the upper circuit board 4 is reduced, which leads to a decrease of the power supply device 1 in size.

In the present embodiment, each of the conductive members 20 has the core portion 22 and the retaining portion 21. The retaining portion 21 is formed at the one end portion 22A of the core portion 22 in each of the conductive members 20 so that the retaining portion 21 protrudes from the core portion 22 perpendicularly to the direction in which the core portion 22 extends and is caught on the lower circuit board 3 or the upper circuit board 4. With this configuration, the conductive members 20 are caught on the lower circuit board 3 or the upper circuit board 4 without falling off from the lower circuit board 3 or the upper circuit board 4. Thus, the conductive members 20 are easily fixed to the lower circuit board 3 and the upper circuit board 4.

In the present embodiment, the diameter of the core portion 22 of each of the conductive members 20 is less than the diameter of the body portion 13 of each of the circuit board coupling members 10, so that the regions of the lower circuit board 3 and the upper circuit board 4, which are occupied for the connection between the electrical signal lines on the lower circuit board 3 and the electrical signal lines on the upper circuit board 4, are further reduced when the electrical signal lines are connected through the conductive members 20. For example, as compared with a case where the upper circuit board 4 and the lower circuit board 3 are connected by only the circuit board coupling members 10 without using the conductive members 20 each having the diameter less than the diameter of the body portion 13 of each of the circuit board coupling members 10 and a case where the diameter of the core portion 22 of each of the conductive members 22 is the same as that of the body portion 13 of each of the circuit board coupling members 10, the regions of the lower circuit board 3 and the upper circuit board 4, which are occupied for the connection between the electrical signal lines, are reduced by also using the conductive members 20 each having the diameter less than the diameter of the body portion 13 of each of the circuit board coupling members 10 in addition to the circuit board coupling members 10. This further simplifies the layouts of the lower circuit board 3 and the upper circuit board 4. The diameter of the body portion 13 of each of the circuit board coupling members is greater than that of the core portion 22 of each of the conductive members 20, so that a coupling strength between the lower circuit board 3 and the upper circuit board 4 increases. Furthermore, the body portion 13 of each of the circuit board coupling members 10 is thicker than the core portion 22 of each of the 10 conductive members 20, so that a large current can flow through the circuit board coupling members 10.

In the present embodiment, the power elements are mounted on the lower circuit board 3 and the control elements are mounted on the upper circuit board 4, which simplifies structures of the wiring patterns formed on the lower circuit board 3 and the upper circuit board 4. Accordingly, the layouts of the lower circuit board 3 and the upper circuit board 4 are simplified. Furthermore, the lower circuit board 3 and the upper circuit board 4 are accommodated in the housing 2, and the lower circuit board 3 is thermally coupled to the housing 2, so that the heat generated from the power elements mounted on the lower circuit board 3 are effectively dissipated to the housing 2.

In the present embodiment, when the power supply device 1 is manufactured, the conductive members 20 are inserted through the through holes 32 and the through holes 42 in the state where the lower circuit board 3 and the upper circuit board 4 are positioned by the circuit board coupling members 10. Accordingly, the conductive members 20 are easily inserted through the through holes 32 and the through holes 42.

In the present embodiment, after the lower circuit board 3 and the upper circuit board 4 are coupled by the plurality of the circuit board coupling members 10, the conductive members 20 are inserted through the through holes 32 and the through holes 42, and then, fixed to the lower circuit board 3 and the upper circuit board 4 by the solder. Thus, the lower circuit board 3 and the upper circuit board 4 are easily electrically connected to each other through the conductive members 20.

In the present embodiment, when the power supply device 1 is manufactured, after the conductive members 20 are inserted through the through holes 32 and the through holes 42, the circuit board coupling members 10 and the conductive members 20 are fixed to the lower circuit board 3 and the upper circuit board 4 by applying the solder 50 on the lower circuit board 3 and the upper circuit board 4, melting the applied solder 50, and cooling the melted solder 50. Thus, in a state where the circuit board coupling members 10 and the conductive members 20 are assembled to the lower circuit board 3 and the upper circuit board 4, the circuit board coupling members 10 and the conductive members 20 are simultaneously fixed to the lower circuit board 3 and the upper circuit board 4. As a result, efficiency of the work of fixing the circuit board coupling members 10 and the conductive members 20 to the lower circuit board 3 and the upper circuit board 4 is enhanced.

In the present embodiment, after the protruding portion 12 of each of the circuit board coupling members 10, which has been fitted into the corresponding positioning hole 41 of the upper circuit board 4, is fixed to the upper circuit board 4 by the solder 50, the upper circuit board 4 is turned over, and then, the protruding portion 11 of the circuit board coupling member 10, which has been fitted to the corresponding positioning hole 31 of the lower circuit board 3, is fixed to the lower circuit board 3 by the solder 50. Thus, the lower circuit board 3 and the upper circuit board 4 are easily and surely coupled to each other by the circuit board coupling members 10.

The present disclosure is not limited to the above-described embodiment. For example, in the above-described embodiment, each of the positioning holes 31 and each of the through holes 32 have the circular shape; however, the present disclosure is not limited thereto. For example, the shapes of each of the positioning holes 31 and each of the through holes 32 are not limited to a circle but may be an ellipse, an oval, or a polygonal shape such as a triangle or a rectangle.

For example, in the above-described embodiment, each of the positioning holes 41 and each of the through holes 42 have the circular shape; however, the present disclosure is not limited thereto. For example, the shapes of each of the positioning holes 41 and each of the through holes 42 are not limited to a circle but may be an ellipse, an oval, or a polygonal shape such as a triangle or a rectangle.

In the above-described embodiment, the body portion 13 of each of the circuit board coupling members 10 has the columnar shape extending in the direction D1; however, the present disclosure is not limited thereto. For example, the body portion 13 may have a pillar shape having a bottom surface whose shape is an oval or an ellipse or having a bottom surface whose shape is a polygonal shape such as a triangle or a rectangle. In addition, the body portion 13 of each of the circuit board coupling members 10 may have a cylindrical shape.

Furthermore, the body portion 13 of each of the circuit board coupling members 10 may have a pillar shape or a tubular shape such that a center portion of the side surface 13A in the direction D1 is convex along the direction D2 toward an outside of the body portion 13 or concave along the direction D2 toward an inside of the body portion 13.

In the above-described embodiment, the top surface 13B and the bottom surface 13C of the body portion 13 of each of the circuit board coupling members 10 are even surfaces; however, the present disclosure is not limited thereto. For example, the top surface 13B and the bottom surface 13C may be uneven. Furthermore, the top surface 13B and the bottom surface 13C may be inclined relative to the direction D1.

In the above-described embodiment, the protruding portion 11 of each of the circuit board coupling members 10 has the columnar shape; however, the present disclosure is not limited thereto. For example, the protruding portion 11 may have a pillar shape having a bottom surface whose shape is an oval or an ellipse or having a bottom surface whose shape is a polygonal shape such as a triangle or a rectangle, in correspondence with the shape of the corresponding positioning hole 31.

In the above-described embodiment, the protruding portion 12 of each of the circuit board coupling members 10 has the columnar shape; however, the present disclosure is not limited thereto. For example, the protruding portion 12 may have a pillar shape having a bottom surface whose shape is an oval or an ellipse or having a bottom surface whose shape is a polygonal shape such as a triangle or a rectangle, in correspondence with the shape of the corresponding positioning hole 41.

In the above-described embodiment, the circuit board coupling members 10 each have electrical conductivity, and the circuit board coupling members 10 are each made of metal such as copper; however, the present disclosure is not limited thereto. For example, the circuit board coupling members 10 need not have electrical conductivity, and the circuit board coupling members 10 may be each made of resin.

In the above-described embodiment, in the state where the conductive members 20 pass through the lower circuit board 3 and the upper circuit board 4, the retaining portion 21 of each of the conductive members 20 is disposed on the main surface S5 of the upper circuit board 4; however, the present disclosure is not limited thereto. For example, in the state where the conductive members 20 pass through the lower circuit board 3 and the upper circuit board 4, the retaining portion 21 may be disposed on the main surface S2 of the lower circuit board 3. That is, the retaining portion 21 is caught on the lower circuit board 3 and fixed to the lower circuit board 3.

In the above-described embodiment, the retaining portion 21 of each of the conductive members 20 has the columnar shape extending in the direction D2; however, the present disclosure is not limited thereto. For example, the retaining portion 21 may have a pillar shape having a bottom surface whose shape is an oval or an ellipse or having a bottom surface whose shape is a polygonal shape such as a triangle or a quadrangle. Furthermore, the retaining portion 21 may extend from the core portion 22 of each of the conductive members 20 in the direction D2. That is, the conductive members 20 each may have an L-shape when viewed in a direction perpendicular to a surface to which the retaining portion 21 and the core portion 22 are fixed. Even in this case, since the retaining portion 21 faces the upper circuit board 4, the conductive member 20 is caught on the upper circuit board 4 without falling off from the upper circuit board 4.

In the above-described embodiment, the bottom surface 21A of the retaining portion 21 is the even surface; however, the present disclosure is not limited thereto. For example, the bottom surface 21A may be uneven. In addition, the bottom surface 21A may be inclined relative to the direction D1.

In the above-described embodiment, the core portion 22 of each of the conductive members 20 has the columnar shape; however, the present disclosure is not limited thereto. For example, the core portion 22 may have a pillar shape having a bottom surface whose shape is an oval or an ellipse or having a bottom surface whose shape is a polygonal shape such as a triangle or a quadrangle.

Furthermore, the other end portion 22B of each of the conductive members 20 tapers toward the distal end thereof in the direction D1; however, the other end portion 22B of each of the conductive members 20 need not taper.

In the above-described embodiment, the electronic components 30 are mounted on the lower circuit board 3 and the electronic components 40 are mounted on the upper circuit board 4; however, the present embodiment is not limited thereto. For example, in the power supply device 1, only one of the electronic components 30 or the electronic components 40 may be mounted. That is, electronic components may be mounted on only one of the lower circuit board 3 or the upper circuit board 4.

1. A power supply device comprising:
a first circuit board;
a second circuit board that is disposed so that the second circuit board faces the first circuit board; and
a plurality of circuit board coupling members through which the first circuit board is coupled to the second circuit board, wherein
each of the circuit board coupling members includes a body portion, a first protruding portion, and a second protruding portion,
the body portion determines positions of the first circuit board and the second circuit board in a direction in which the first circuit board and the second circuit board face each other with one end surface of the body portion in contact with the first circuit board and with the other end surface of the body portion in contact with the second circuit board,
the first protruding portion protrudes from the one end surface of the body portion and positions the body portion relative to the first circuit board in a direction perpendicular to the direction in which the first circuit board and the second circuit board face each other,
the second protruding portion protrudes from the other end surface of the body portion and positions the body portion relative to the second circuit board in the direction perpendicular to the direction in which the first circuit board and the second circuit board face each other,
a plurality of first positioning holes in which the first protruding portions are fitted is formed in the first circuit board, and
a plurality of second positioning holes in which the second protruding portions are fitted is formed in the second circuit board.

2. The power supply device according to claim 1, wherein
the circuit board coupling members each have electrical conductivity and electrically connect the first circuit board to the second circuit board,
the first protruding portions are fixed to the first circuit board by solder, and
the second protruding portions are fixed to the second circuit board by the solder.

3. The power supply device according to claim 1, further comprising
a conductive member through which the first circuit board and the second circuit board are electrically connected to each other, wherein
the first circuit board has a first through hole through which the conductive member passes,
the second circuit board has a second through hole through which the conductive member passes, and
the conductive member is fixed to the first circuit board and the second circuit board by solder.

4. The power supply device according to claim 3, wherein
the conductive member has a core portion and a retaining portion that is formed at one end portion of the core portion so that the retaining portion protrudes from the core portion perpendicularly to a direction in which the core portion extends and is caught on the first circuit board or the second circuit board.

5. The power supply device according to claim 4, wherein
the body portions and the core portion have a columnar shape, and
a diameter of the core portion is less than a diameter of each of the body portions.

6. The power supply device according to claim 1, wherein
a power element is mounted on the first circuit board,
a control element is mounted on the second circuit board, and
the first circuit board and the second circuit board are accommodated in a housing, and
the first circuit board is thermally coupled to the housing.

7. A method of manufacturing the power supply device according to claim 3, comprising:
coupling the first circuit board and the second circuit board through the plurality of the circuit board coupling members; and
inserting the conductive member into the first through hole and the second through hole after coupling the first circuit board and the second circuit board through the plurality of the circuit board coupling members.

8. The method of manufacturing the power supply device according to claim 7, further comprising
after inserting the conductive member into the first through hole and the second through hole, fixing the circuit board coupling members and the conductive member to the first circuit board and the second circuit board by:
applying the solder on the first circuit board and the second circuit board;
melting the applied solder; and
cooling the melted solder.
